(19) United States
(12) Patent Application Publication
(10) Pub. No.: US 2014/0203850 A1
(43) Pub. Date: Jul. 24, 2014

(54) POWER MANAGED SYNCHRONIZERS FOR ASYNCHRONOUS INPUT SIGNALS

(71) Applicant: APPLE INC., Cupertino, CA (US)

(72) Inventors: Gilbert Herbeck, Livermore, CA (US); Erik Machnicki, San Jose, CA (US)

(73) Assignee: APPLE INC., Cupertino, CA (US)

(21) Appl. No.: 13/749,049

(22) Filed: Jan. 24, 2013

(51) Int. Cl. H03L 7/24

(52) U.S. Cl. CPC H03L 7/24
USPC 327/151; 327/144

(57) ABSTRACT

Clock-gated synchronizer circuitry includes a number of clock-gated synchronizers, with each clock-gated synchronizer configured to synchronize an asynchronous input signal into a clock domain. The circuitry also includes a clock gater coupled to a clock input of the plurality of clock-gated synchronizers and coupled to receive an input clock and an enable signal. The clock gater is configured to provide the input clock to the plurality of synchronizers only upon receiving the enable signal. The circuitry also includes an enable generator coupled to receive the asynchronous input signals and configured to generate the enable signal for the clock gater responsive to the asynchronous input signals.

### BACKGROUND

1. Technical Field

This disclosure relates generally to synchronizer circuitry, and more particularly to apparatus, devices, methods, and processors for reducing power consumption of synchronizers.

2. Description of the Related Art

In recent years, mobile devices such as smart phones and tablet computers have become increasingly sophisticated. In addition to supporting telephone calls, many mobile devices now provide access to the internet, email, text messaging, and navigation using the global positioning system (GPS). Mobile devices that support such sophisticated functionality often include many components. Any of the components, and often many, may be coupled to a processor to provide an asynchronous interrupt signals. Such interrupt signals may originate in one clock domain and be synchronized into another clock domain prior to the processor receiving the interrupt signals. Further, many such signals change state (transition from logic high to low or vice versa) very rarely. The synchronizers utilized to synchronize the interrupt signals from one clock domain into another, however, are typically clocked continuously. Such synchronizers, when clocked continuously but utilized rarely, inefficiently consume power.

### SUMMARY

Various example apparatus for apparatus, devices, methods, and processors for reducing power consumption of synchronizers are disclosed. Example apparatus may include a number of clock-gated synchronizers, with each clock-gated synchronizer configured to synchronize an asynchronous input signal into a clock domain. Such apparatus may also include a clock gater coupled to a clock input of the plurality of clock-gated synchronizers and coupled to receive an input clock and an enable signal. The clock gater may be configured to provide the input clock to the plurality of synchronizers only upon receiving the enable signal. Such apparatus may also include an enable generator coupled to receive the asynchronous input signals and configured to generate the enable signal for the clock gater responsive to the asynchronous input signals.

Also disclosed are devices for reducing power consumption of synchronizers. Such devices may be implemented in a variety of forms including, as one example, a wireless mobile device. Such devices may include a processor configured to receive one or more asynchronous input signal as well as a synchronizer circuit. Such a synchronizer circuit may be configured in a manner similar to that of the example apparatus described above.

Also disclosed are methods for reducing power consumption of synchronizers. Such methods may include receiving, by an enable generator, one or more asynchronous input signals and, responsive to receiving the one or more asynchronous input signals, providing an enable signal synchronized into a clock domain to a clock gater. In such methods, the clock gater may provide a clock signal to a plurality of clock-gated synchronizers responsive to receiving the enable signal and each clock gated synchronizer may synchronize a corresponding one of the asynchronous input signals into the clock domain based on the clock signal.

Processors configured for reduced power consumption of synchronizers are also disclosed. Such processors may include an interrupt controller configured to receive one or more asynchronous interrupt signals and a synchronizer circuit. The synchronizer circuit may include a plurality of clock-gated synchronizers, with each clock-gated synchronizer configured to synchronize one of the asynchronous interrupt signals into a clock domain. A clock gater may be coupled to a clock input of the plurality of clock-gated synchronizers and coupled to receive an input clock and an enable signal. The clock gater may be configured to provide the input clock to the plurality of synchronizers only upon receiving the enable signal. The synchronizer circuit may also include an enable generator coupled to receive the asynchronous interrupt signals and configured to generate the enable signal for the clock gater responsive to the asynchronous interrupt signals.

### BRIEF DESCRIPTION OF THE DRAWINGS

FIG. 1 sets forth a block diagram of one embodiment of a wireless communication system.

FIG. 2 sets forth a block diagram of one embodiment of a wireless communication device shown in FIG. 1.

FIG. 3 sets forth a block diagram of an example clock gated synchronizer circuit.

FIG. 4 sets forth a block diagram of another example clock gated synchronizer circuit.

FIG. 5 sets forth a flowchart illustrating an example method of reducing power consumption of synchronizers.

Specific embodiments are shown by way of example in the drawings and will herein be described in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

As used throughout this application, the word “may” is used in a permissive sense (i.e., meaning having the potential to), rather than the mandatory sense (i.e., meaning must). Similarly, the words “include,” “including,” and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six, interpretation for that unit/circuit/component.

The scope of the present disclosure includes any feature or combination of features disclosed herein (either explicitly or implicitly), or any generalization thereof, whether or not it mitigates any or all of the problems addressed herein. Accordingly, new claims may be formulated during prosecution of this application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

### DETAILED DESCRIPTION

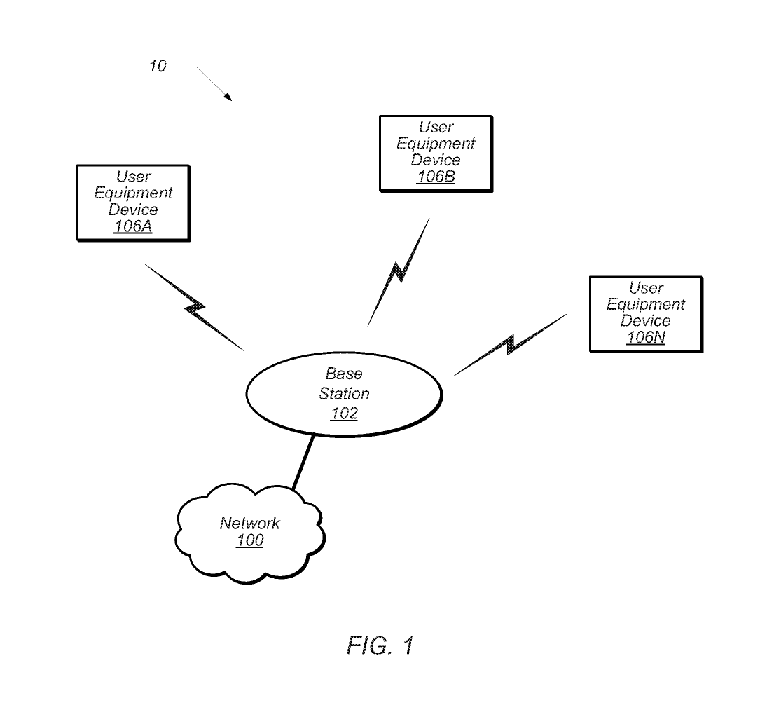

FIG. 1 sets forth a block diagram of one embodiment of a wireless communication system. The system of FIG. 1 is one example of any of a variety of wireless communication systems. The wireless communication system 10 includes a base station 102 which communicates over a wireless transmission medium such as, for example, an over the air interface with one or more user equipment (UE) devices, 106A through 106N. The base station 102 is also coupled a network 100 via another interface, which may be wired or wireless. Components identified by reference designators that include both a number and a letter may be referred to by the only a number where appropriate.

The base station 102 may be a base transceiver station (BTS) or cell site, and may include hardware that enables wireless communication with one or more of the UEs 106. The base station 102 may also be equipped to communicate with the network 100. Thus, the base station 102 may facilitate communication between the UEs 106 and/or between the UEs 106 and the network 100. The communication area (or coverage area) of the base station 102 may be referred to as a “cell.” In various embodiments, the base station 102 and the UEs may be configured to communicate over the transmission medium using any of various wireless communication radio access technologies such as LTE, eHRPD, GSM, CDMA, WLL, WAN, WiFi, WiMAX, etc. In embodiments that communicate using the eHRPD standard, the BTS 102 may be referred to as an HRPD BTS, and the network 100 may include an eAN/ePCF and a number of gateways including HRPD gateway (HSGW), a PDN gateway (P-GW), and a number of policy and packet control functions that may be associated with a service provider, for example.

In one embodiment, each of the UEs 106A-106N may be representative of a device with wireless network connectivity such as a mobile phone, a hand-held device, a computer or a tablet, or virtually any type of wireless device. As described further below, the UE 106 may include at least one processor that is configured to execute program instructions stored in a memory. Accordingly, in some embodiments, the UE 106 may perform one or more portions of the functionality described below by executing such stored instructions. However, in other embodiments, the UE 106 may include one or more hardware elements and/or one or more programmable hardware elements such as an FPGA (field-programmable gate array) that may be configured to perform the one or more portions the functionality described below. In still other embodiments, any combination of hardware and software may be implemented to perform the functionality described below.

In the system 10 of FIG. 1, any of the UEs 106 may include, among other components, a plurality of clock-gated synchronizers. Each clock-gated synchronizer may be configured to synchronize one of a number of asynchronous input signals into a clock domain. The UE 106 may also include a clock gater coupled to a clock input of the plurality of clock-gated synchronizers. The clock gater may be coupled to receive an input clock and an enable signal, where the clock gater provides the input clock to the synchronizers only upon receiving the enable signal. The UE 106 may also include an enable generator coupled to receive the asynchronous input signals and configured to generate the enable signal for the clock gater responsive to the asynchronous input signals. In this way, the synchronizers are clocked only while receiving an asynchronous input signal.

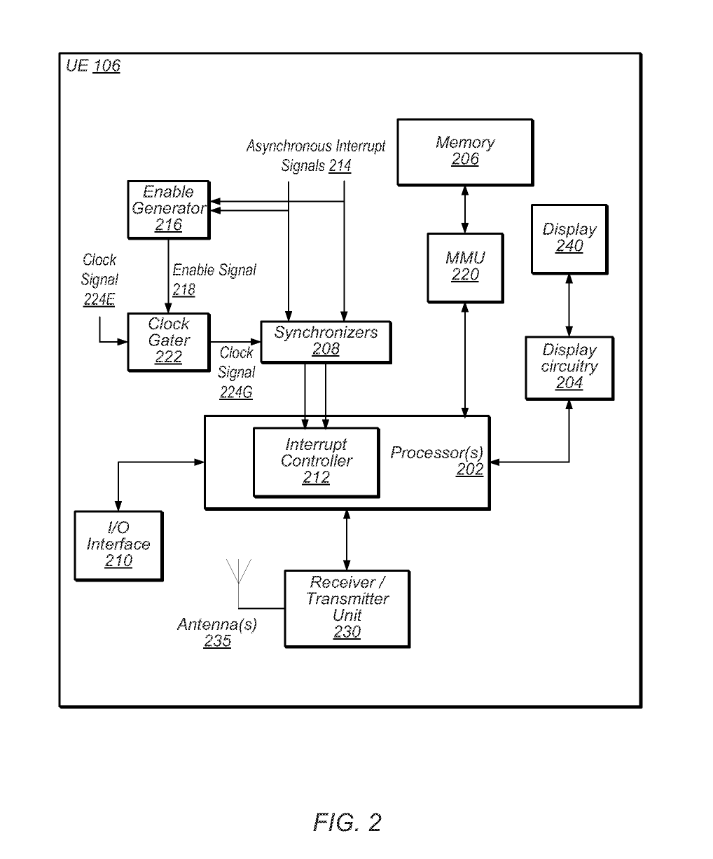

For further explanation, FIG. 2 sets forth a block diagram of one embodiment of a wireless communication device shown in FIG. 1. The UE 106 includes one or more processors 202 (or one or more processor cores 202) which are coupled to display circuitry 204 which is in turn coupled to the display 240. The display circuitry 204 may be configured to perform graphics processing and provide display signals to the display 240.

The one or more processors 202 are also coupled to a memory management unit (MMU) 220 and to a receiver/transmitter (R/T) unit 230. The MMU 220 is coupled to a memory 206. The UE 106 also includes an I/O interface 210 that is coupled to the processor(s) 202, and may be used for coupling the UE 106 to a computer system, or other external device. It is noted that in one embodiment the components shown within UE 106 of FIG. 2 may be manufactured as standalone components. In other embodiments, however, various ones of the components may be part of one or more chipsets or part of a system on chip (SOC) implementation.

In various embodiments, the processors 202 may be representative of a number of different types of processors that may be found in a wireless communication device. For example, the processors 202 may include general processing capability, digital signal processing capability, as well as hardware accelerator functionality, as desired. The processors 202 may include baseband processing and therefore may digitally process the signals received by the R/T unit 230. The processors 202 may also process data that may be transmitted by the R/T unit 230. The processors 202 may also perform a number of other data processing functions such as running an operating system and user applications for the UE 106.

In one embodiment, the MMU 220 may be configured to receive addresses from the one or more processors 202 and to translate those addresses to locations in memory (e.g., memory 206) and/or to other circuits or devices, such as the display circuitry 204, R/T unit 230, and/or display 240. The MMU 220 may also return data to one or more of the processors 202 from the locations in memory 206. The MMU 220 may be configured to perform memory protection and page table translation or set up. In some embodiments, the MMU 220 may be included as a portion of one or more of the processors 202.

The R/T unit 230 may, in one embodiment, include analog radio frequency (RF) circuitry for receiving and transmitting RF signals via the antenna 235 to perform the wireless communication. The R/T unit 230 may also include down-conversion circuitry to lower the incoming RF signals to the baseband or intermediate frequency (IF) as desired. For example, the R/T unit 230 may include various RF and IF filters, local oscillators, mixers, and the like. Since the UE 106 may operate according to a number of radio access technologies, the R/T unit 230 may include a corresponding number of RF front end portions to receive and down-convert, as well as up-convert and transmit the respective RF signals of each technology.

In some embodiments, one or more of the components of the example UE 106 (or components not included in the UE 106) may provide asynchronous interrupt signals 214 to an interrupt controller 212 of the processor 202. The asynchronous interrupt signals 214 may be synchronized into a clock domain by a number of synchronizers 208.

In the example UE 106 of FIG. 2, the synchronizers may be clock-gated by a clock gater 222 that is coupled to receive an input clock 224E and an enable signal 218. The clock gater 222 may be configured to provide a clock 224G to the synchronizers 208 only upon receiving the enable signal 218.

In the example UE 106 of FIG. 2, an enable generator 216 may be coupled to receive the asynchronous interrupt signals 214 and generate the enable signal 218 for the clock gater responsive to the asynchronous interrupt signals. In this way, the synchronizers are provided a clock signal only after the enable generator receives an asynchronous interrupt signal 214.

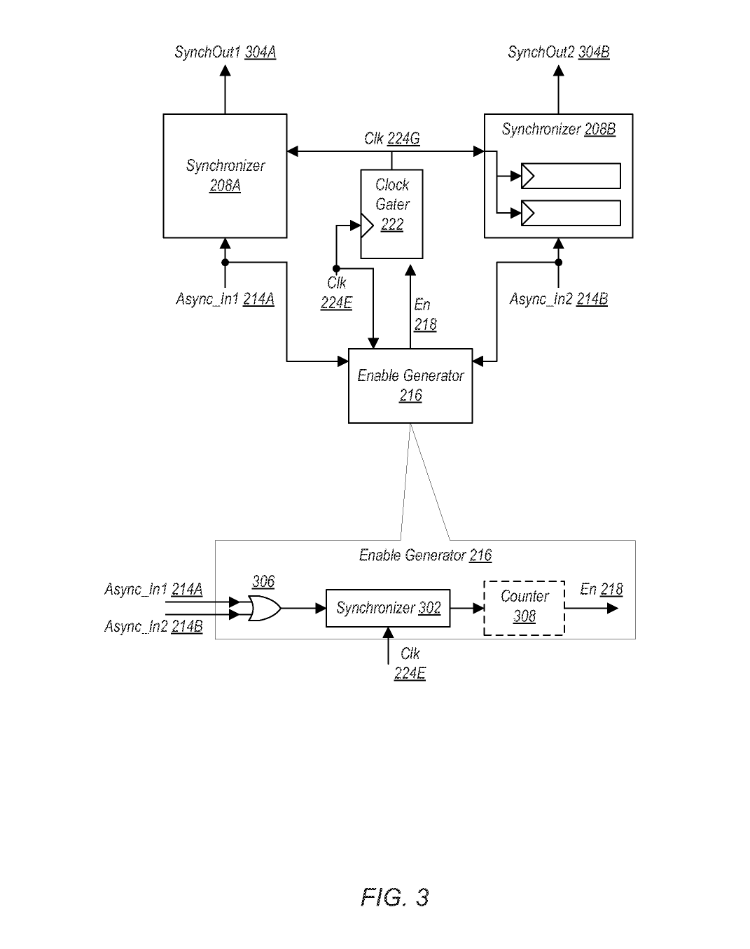

For further explanation, FIG. 3 sets forth a block diagram of an example clock gated synchronizer circuit. The example clock gated synchronizer circuit of FIG. 3 includes two synchronizers 208A, 208B, each of which is configured to receive an asynchronous input signal 214A, 214B and synchronize the asynchronous input signal 214A, 214B into a clock domain based on a input clock 224E. Each synchronizer 208A, 208B provides a synchronized output signal 304A, 304B.

The example clock gated synchronizer circuit of FIG. 3 also includes a clock gater 222 that is coupled to a clock input of the plurality of clock-gated synchronizers 208A, 208B. The clock gater 222 is also coupled to receive an input clock 224E and an enable signal 218. The clock gater 222 is configured to provide a clock 224G to the synchronizers 208A, 208B only upon receiving the enable signal 218.

The example clock gated synchronizer circuit of FIG. 3 also includes an enable generator 216 that is coupled to receive the asynchronous input signals 214A, 214B and is configured to generate the enable signal 218 for the clock gater 222 responsive to the asynchronous input signals 214A, 214B. In the example of FIG. 3, the enable generator includes an OR gate 306 that is coupled to receive the asynchronous input signals 214A, 214B. The example enable generator 216 of FIG. 3 also includes a synchronizer 302 coupled to receive the input clock 224E and configured to synchronize an output of the OR gate 306 to the clock domain based on the input clock 224E. The synchronized output of the OR gate 306 in the example of FIG. 3 may be the enable signal 218. In this way, upon receiving either of the asynchronous input signals 214A, 214B, the enable generator 216 provides a synchronized enable signal to the clock gater to enable the clock gater to provide the input clock to the synchronizers 208A, 208B.

To ensure that the entire asynchronous input signal is synchronized by the synchronizer 208A, 208B, in some embodiments a counter 308 may coupled to the output of the enable generator's 216 synchronizer 302. The counter 308 may be configured to provide the enable signal 218 for a predefined period of time after the synchronizer 302 ceases to provide an output. In this way, if there is some delay between the clock gater 222 being enabled that delay can be propagated and taken into account by the counter, ensuring that the synchronizers 208A, 208B will continue to operate for some predefined period of time after the asynchronous input signal 214A, 214B is removed.

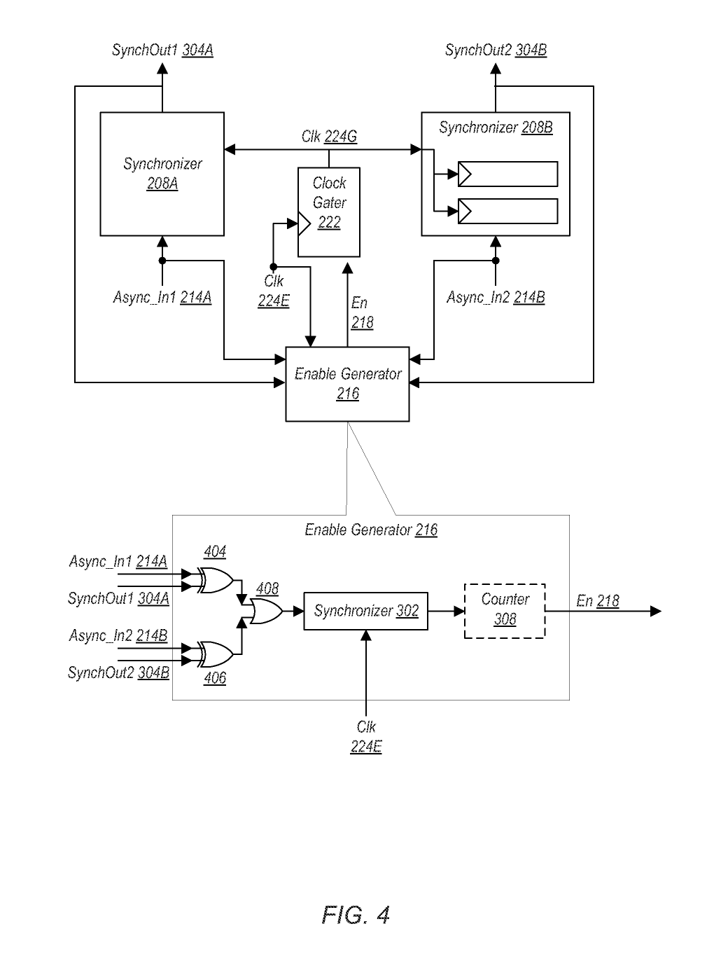

For further explanation, FIG. 4 sets forth a block diagram of another example clock gated synchronizer circuit. The example clock gated synchronizer circuit of FIG. 4 is similar to that depicted in the example of FIG. 3. In the example of FIG. 4, however, the enable generator 216 includes a first XOR gate 404 coupled to receive a first asynchronous input signal 214A and an output 304A of a first synchronizer 208A. The example enable generator 216 of FIG. 4 also includes a second XOR gate 406 coupled to receive a second asynchronous input signal 214B and an output 304B of a second synchronizer 208B. The example enable generator of FIG. 4 also includes an OR gate 408 coupled to receive, as inputs, the output of the first XOR gate 404 and the second XOR gate 406. The example enable generator 216 of FIG. 4 also includes a synchronizer 302 coupled to receive the input clock 224E and configured to synchronize an output of the OR gate 408 to the clock domain based on the input clock 224E. In some embodiments, the synchronized output of the OR gate 408 may be the enable signal 218. As mentioned above, the enable generator 216 may also include a counter 308 that operates as described above with respect to FIG. 3.

The XOR gates 404, 406 of the example enable generator 216 of FIG. 4 are configured such that the enable generator provides an enable signal upon receiving an asynchronous input signal and ceases providing the enable signal when the asynchronous input signal is synchronized into the clock domain. In this way, the synchronizers are only clocked until the asynchronous input signals are synchronized.

It is noted, that although two XOR gates are depicted in the example of FIG. 4, an array of any number of XOR gates may be implemented as well. In such embodiments, the array of XOR gates may include one XOR gate for each asynchronous signal.

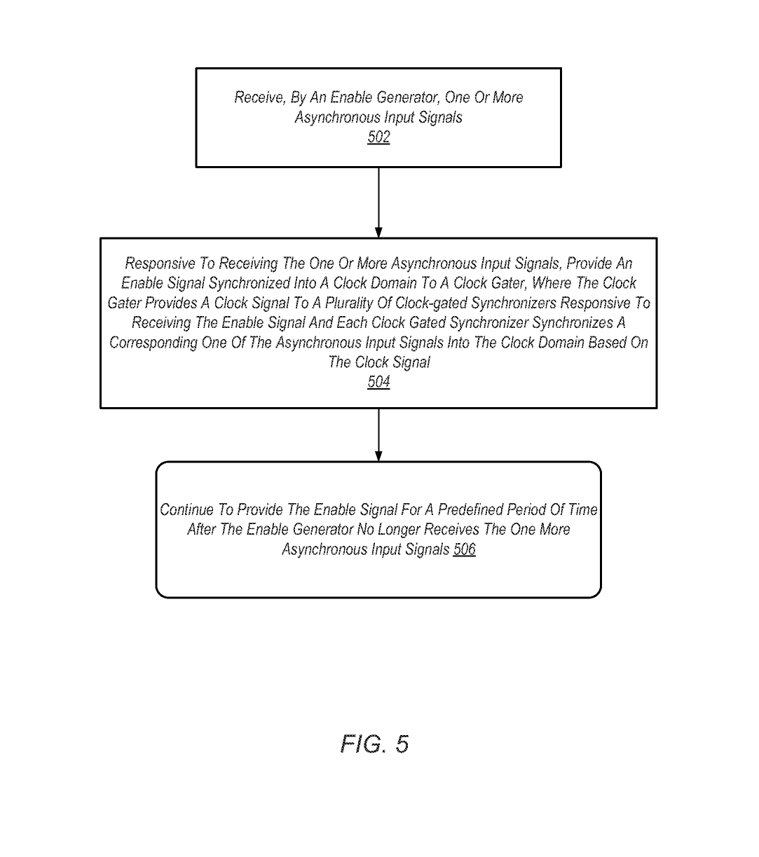

For further explanation, FIG. 5 sets forth a flowchart illustrating an example method of reducing power consumption of synchronizers. The method of FIG. 5 includes receiving 502, by an enable generator, one or more asynchronous input signals. In some embodiments, the enable generator includes an OR gate and a synchronizer, where the synchronizer is coupled to receive an output signal of the OR gate and the clock signal and receiving 502 the one or more asynchronous input signals is carried out by receiving, by the OR gate, the one or more asynchronous input signals. In other embodiments, the enable generator includes a first XOR gate, a second XOR gate, an OR gate, and a synchronizer. In such an embodiment, receiving 502 the one or more asynchronous input signals may be carried out by: receiving a first asynchronous input signal and an output of a first synchronizer configured to synchronize the first asynchronous input signal by the first XOR gate; receiving a second asynchronous input signal and an output of a second synchronizer configured to synchronize the second asynchronous input signal by the second XOR gate; and receiving, by the OR gate, the output of the first XOR gate and the second XOR gate.

Responsive to receiving 502 the one or more asynchronous input signals, the method of FIG. 5 continues providing 504 an enable signal synchronized into a clock domain to a clock gater. In the method of FIG. 5, the clock gater provides a clock signal to a plurality of clock-gated synchronizers responsive to receiving the enable signal and each clock gated synchronizer synchronizes a corresponding one of the asynchronous input signals into the clock domain based on the clock signal.

In embodiments in which the enable generator includes an OR gate (but no XOR gates), providing 504 the enable signal synchronized into the clock domain to the clock gater may be carried out by synchronizing, by the enable generator synchronizer, the output signal of the OR gate into the clock domain based on the clock signal and providing the synchronized signal to the clock gater as the enable signal. In embodiments in which the enable generator includes XOR gates, providing 504 the enable signal synchronized into the clock domain to the clock gater may be carried out by synchronizing, by the enable generator synchronizer, the output signal of the OR gate into the clock domain based on the clock signal and providing the synchronized signal to the clock gater as the enable signal.

The method of FIG. 5 also includes continuing 506 to provide the enable signal for a predefined period of time after the enable generator no longer receives the one or more asynchronous input signals. Continuing 506 to provide the enable signal for a predefined period of time may be carried out in various ways including, for example, through use of a counter such as those depicted in the examples of FIG. 3 and FIG. 4.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. An apparatus comprising:
a plurality of clock-gated synchronizers, each clock-gated synchronizer configured to synchronize an asynchronous input signal into a clock domain;
a clock gater coupled to a clock input of the plurality of clock-gated synchronizers and coupled to receive an input clock and an enable signal, wherein the clock gater is configured to provide the input clock to the plurality of synchronizers only upon receiving the enable signal; and
an enable generator coupled to receive the asynchronous input signals and configured to generate the enable signal for the clock gater responsive to the asynchronous input signals.

2. The apparatus of claim 1, wherein the enable generator further comprises:
an OR gate coupled to receive the asynchronous input signals;
a synchronizer coupled to receive the input clock and configured to synchronize an output of the OR gate to the clock domain based on the input clock, wherein the synchronized output of the OR gate comprises the enable signal.

3. The apparatus of claim 1, wherein the enable generator further comprises:
an OR gate coupled to receive the asynchronous input signals;
a synchronizer configured to synchronize an output of the OR gate to the clock domain based on the input clock; and
a counter coupled to receive the output of the synchronizer and configured to provide the enable signal to the clock gater while receiving the output of the synchronizer and for a predefined period of time thereafter.

4. The apparatus of claim 1, wherein the enable generator further comprises:
a first XOR gate coupled to receive a first asynchronous input signal and an output of a first synchronizer configured to synchronize the first asynchronous input signal;
a second XOR gate coupled to receive a second asynchronous input signal and an output of a second synchronizer configured to synchronize the second asynchronous input signal;
an OR gate coupled to receive, as inputs, the output of the first XOR gate and the second XOR gate; and
a synchronizer coupled to receive the input clock and configured to synchronize an output of the OR gate to the clock domain based on the input clock, wherein the synchronized output of the OR gate comprises the enable signal.

5. The apparatus of claim 1, wherein the enable generator further comprises:
a first XOR gate coupled to receive a first asynchronous input signal and an output of a first synchronizer configured to synchronize the first asynchronous input signal;
a second XOR gate coupled to receive a second asynchronous input signal and an output of a second synchronizer configured to synchronize the second asynchronous input signal;
an OR gate coupled to receive, as inputs, the output of the first XOR gate and the second XOR gate; and
a synchronizer coupled to receive the input clock and configured to synchronize an output of the OR gate to the clock domain based on the input clock; and
a counter coupled to receive the output of the synchronizer and configured to provide the enable signal to the clock gater while receiving the output of the synchronizer and for a predefined period of time thereafter.

6. A device comprising:
a processor configured to receive one or more asynchronous input signals; and
a synchronizer circuit comprising:
a plurality of clock-gated synchronizers, each clock-gated synchronizer configured to synchronize one of the asynchronous input signals into a clock domain;
a clock gater coupled to a clock input of the plurality of clock-gated synchronizers and coupled to receive an input clock and an enable signal, wherein the clock gater is configured to provide the input clock to the plurality of synchronizers only upon receiving the enable signal; and
an enable generator coupled to receive the asynchronous input signals and configured to generate the enable signal for the clock gater responsive to the asynchronous input signals.

7. The device of claim 6, wherein the enable generator further comprises:
an OR gate coupled to receive the asynchronous input signals;
a synchronizer coupled to receive the input clock and configured to synchronize an output of the OR gate to the clock domain based on the input clock, wherein the synchronized output of the OR gate comprises the enable signal.

8. The device of claim 6, wherein the enable generator further comprises:
an OR gate coupled to receive the asynchronous input signals;
a synchronizer configured to synchronize an output of the OR gate to the clock domain based on the input clock; and
a counter coupled to receive the output of the synchronizer and configured to provide the enable signal to the clock gater while receiving the output of the synchronizer and for a predefined period of time thereafter.

9. The device of claim 6, wherein the enable generator further comprises:
a first XOR gate coupled to receive a first asynchronous input signal and an output of a first synchronizer configured to synchronize the first asynchronous input signal;
a second XOR gate coupled to receive a second asynchronous input signal and an output of a second synchronizer configured to synchronize the second asynchronous input signal;
an OR gate coupled to receive, as inputs, the output of the first XOR gate and the second XOR gate; and
a synchronizer coupled to receive the input clock and configured to synchronize an output of the OR gate to the clock domain based on the input clock, wherein the synchronized output of the OR gate comprises the enable signal.

10. The device of claim 6, wherein the enable generator further comprises:
a first XOR gate coupled to receive a first asynchronous input signal and an output of a first synchronizer configured to synchronize the first asynchronous input signal;
a second XOR gate coupled to receive a second asynchronous input signal and an output of a second synchronizer configured to synchronize the second asynchronous input signal;
an OR gate coupled to receive, as inputs, the output of the first XOR gate and the second XOR gate; and
a synchronizer coupled to receive the input clock and configured to synchronize an output of the OR gate to the clock domain based on the input clock; and
a counter coupled to receive the output of the synchronizer and configured to provide the enable signal to the clock gater while receiving the output of the synchronizer and for a predefined period of time thereafter.

11. The device of claim 6, wherein the device further comprises a wireless mobile device.

12. The device of claim 6, wherein the processor further comprises an interrupt controller and each asynchronous input signal comprises an asynchronous interrupt signal.

13. A method comprising:
receiving, by an enable generator, one or more asynchronous input signals; and
responsive to receiving the one or more asynchronous input signals, providing an enable signal synchronized into a clock domain to a clock gater, wherein:
the clock gater provides a clock signal to a plurality of clock-gated synchronizers responsive to receiving the enable signal and each clock gated synchronizer synchronizes a corresponding one of the asynchronous input signals into the clock domain based on the clock signal.

14. The method of claim 13 wherein:
the enable generator further comprises an OR gate and a synchronizer, wherein the synchronizer is coupled to receive an output signal of the OR gate and the clock signal;
receiving the one or more asynchronous input signals further comprises receiving, by the OR gate, the one or more asynchronous input signals; and
providing the enable signal synchronized into the clock domain to the clock gater further comprises synchronizing, by the synchronizer, the output signal of the OR gate into the clock domain based on the clock signal and providing the synchronized signal to the clock gater as the enable signal.

15. The method of claim 13, wherein:
the enable generator further comprises an OR gate, a synchronizer and a counter, wherein the synchronizer is coupled to receive an output signal of the OR gate and the clock signal and the counter is configured to receive an output signal of the synchronzier;
receiving the one or more asynchronous input signals further comprises receiving by the OR gate, the one or more asynchronous input signals; and
providing the enable signal synchronized into the clock domain to the clock gater further comprises:
synchronizing, by the synchronizer, the output signal of the OR gate into the clock domain based on the clock signal,
providing the synchronized signal to the counter;
responsive to receiving the synchronized signal, providing, by the counter, the synchronized signal to the clock gater as the enable signal; and
continuing to provide, by the counter, the synchronized signals as the enable signal for a predefined period of time after the synchronized signal is no longer received by the counter.

16. The method of claim 13, wherein:
the enable generator further comprises a first XOR gate, a second XOR gate, an OR gate, and a synchronizer;
receiving the one or more asynchronous input signals further comprises:
receiving a first asynchronous input signal and an output of a first synchronizer configured to synchronize the first asynchronous input signal by the first XOR gate;
receiving a second asynchronous input signal and an output of a second synchronizer configured to synchronize the second asynchronous input signal by the second XOR gate;
receiving, by the OR gate, the output of the first XOR gate and the second XOR gate; and
providing the enable signal synchronized into the clock domain to the clock gater further comprises synchronizing, by the synchronizer, the output signal of the OR gate into the clock domain based on the clock signal and providing the synchronized signal to the clock gater as the enable signal

17. The method of claim 13, wherein:
the enable generator further comprises a first XOR gate, a second XOR gate, an OR gate, a synchronizer, and a counter;
receiving the one or more asynchronous input signals further comprises:
receiving a first asynchronous input signal and an output of a first synchronizer configured to synchronize the first asynchronous input signal by the first XOR gate;
receiving a second asynchronous input signal and an output of a second synchronizer configured to synchronize the second asynchronous input signal by the second XOR gate;
receiving, by the OR gate, the output of the first XOR gate and the second XOR gate; and
providing the enable signal synchronized into the clock domain to the clock gater further comprises:
synchronizing, by the synchronizer, the output signal of the OR gate into the clock domain based on the clock signal;
providing the synchronized signal to the counter;
responsive to receiving the synchronized signal, providing, by the counter, the synchronized signal to the clock gater as the enable signal; and
continuing to provide, by the counter, synchronized signal as the enable signal for a predefined period of time after the synchronized signal is no longer received by the counter.

18. A processor, comprising:
an interrupt controller configured to receive one or more asynchronous interrupt signals; and
a synchronizer circuit comprising:
a plurality of clock-gated synchronizers, each clock-gated synchronizer configured to synchronize one of the asynchronous interrupt signals into a clock domain;
a clock gater coupled to a clock input of the plurality of clock-gated synchronizers and coupled to receive an input clock and an enable signal, wherein the clock gater is configured to provide the input clock to the plurality of synchronizers only upon receiving the enable signal; and
an enable generator coupled to receive the asynchronous interrupt signals and configured to generate the enable signal for the clock gater responsive to the asynchronous interrupt signals.

19. The processor of claim 18, wherein the enable generator further comprises:
an OR gate coupled to receive the asynchronous interrupt signals;
a synchronizer coupled to receive the input clock and configured to synchronize an output of the OR gate to the clock domain based on the input clock, wherein the synchronized output of the OR gate comprises the enable signal.

20. The processor of claim 18, wherein the enable generator further comprises:
an OR gate coupled to receive the asynchronous interrupt signals;
a synchronizer configured to synchronize an output of the OR gate to the clock domain based on the input clock; and
a counter coupled to receive the output of the synchronizer and configured to provide the enable signal to the clock gater while receiving the output of the synchronizer and for a predefined period of time thereafter.

21. The processor of claim 18, wherein the enable generator further comprises:
a first XOR gate coupled to receive a first asynchronous interrupt signal and an output of a first synchronizer configured to synchronize the first asynchronous interrupt signal;
a second XOR gate coupled to receive a second asynchronous interrupt signal and an output of a second synchronizer configured to synchronize the second asynchronous interrupt signal;
an OR gate coupled to receive, as inputs, the output of the first XOR gate and the second XOR gate; and
a synchronizer coupled to receive the input clock and configured to synchronize an output of the OR gate to the clock domain based on the input clock, wherein the synchronized output of the OR gate comprises the enable signal.

22. The processor of claim 18, wherein the enable generator further comprises:
a first XOR gate coupled to receive a first asynchronous interrupt signal and an output of a first synchronizer configured to synchronize the first asynchronous interrupt signal;
a second XOR gate coupled to receive a second asynchronous interrupt signal and an output of a second synchronizer configured to synchronize the second asynchronous interrupt signal;
an OR gate coupled to receive, as inputs, the output of the first XOR gate and the second XOR gate; and
a synchronizer coupled to receive the input clock and configured to synchronize an output of the OR gate to the clock domain based on the input clock; and
a counter coupled to receive the output of the synchronizer and configured to provide the enable signal to the clock gater while receiving the output of the synchronizer and for a predefined period of time thereafter.
